(19) United States
(12) Patent Application Publication
(10) Pub. No.: US 2026/0303939 A1
(43) Pub. Date: Oct. 1, 2026

(54) CAMERA MODULE

(71) Applicant: SAMSUNG ELECTRO-MECHANICS CO., LTD., Suwon-si (KR)

(72) Inventor: Sang Yong KIM, Suwon-si (KR)

(73) Assignee: SAMSUNG ELECTRO-MECHANICS CO., LTD., Suwon-si (KR)

(21) Appl. No.: 19/535,009

(22) Filed: Feb. 10, 2026

(30) Foreign Application Priority Data
Mar. 28, 2025 (KR) 10-2025-0040627

(51) Int. Cl. H04N 23/55; H04N 23/52

(52) U.S. Cl. CPC H04N 23/55; H04N 23/52

(57) ABSTRACT

A camera module includes a first lens group and a second lens group sequentially disposed along an optical axis; a lens barrel configured to accommodate the first lens group and the second lens group; and a moisture-absorbing member disposed in a groove in the lens barrel. The lens barrel includes a first vent through which the groove is connected to a space between the first lens group and the second lens group, and a second vent through which the groove is connected to an outer space of the lens barrel.

### CROSS-REFERENCE TO RELATED APPLICATIONS

This application claims the benefit under 35 USC 119(a) of Korean Patent Application No. 10-2025-0040627 filed on Mar. 28, 2025, in the Korean Intellectual Property Office, the entire disclosure of which is incorporated herein by reference for all purposes.

### BACKGROUND

### 1. Field

The present disclosure relates to a camera module capable of reducing condensation of a lens.

### 2. Description of the Background

A camera module may include a plurality of lenses or a plurality of lens groups. For example, the camera module may include a frontmost lens (or a first lens group) exposed outwardly and a rear lens (or a second lens group) disposed between the frontmost lens and an image sensor. A surveillance camera module may be mainly installed outdoors, and thus be easily affected by an external environment. For example, the frontmost lens (or the first lens group) of the camera module mounted on a vehicle is likely to be heated to a high temperature by direct sunlight, latent heat from a road, or the like. In contrast, the rear lens (or the second lens group) of the camera module may be positioned inside a vehicle, and thus may be maintained at a predetermined temperature. However, such a temperature difference between the first lens group and the second lens group may cause a dew condensation phenomenon between the first lens group and the second lens group, thereby deteriorating the resolution of the camera module.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a camera module includes a first lens group and a second lens group sequentially disposed along an optical axis; a lens barrel configured to accommodate the first lens group and the second lens group; and a moisture-absorbing member disposed in a groove in the lens barrel. The lens barrel includes a first vent through which the groove is connected to a space between the first lens group and the second lens group, and a second vent through which the groove is connected to an outer space of the lens barrel.

The first vent and the second vent may be disposed at intervals in a circumferential direction around the optical axis of the lens barrel.

The first vent may face a first direction intersecting the optical axis of the lens barrel, and the second vent may face in a second direction intersecting the optical axis.

A number of first vents and a number of second vents may be different.

The first vent and the second vent may have different sizes.

The camera module may further include a buffer member disposed in the groove.

In another general aspect, a camera module includes a first lens group and a second lens group sequentially disposed along an optical axis; a lens barrel configured to accommodate the second lens group; and a cover member configured to fix the first lens group to the lens barrel. The lens barrel includes a groove, a first vent through which the groove is connected to a space between the first lens group and the second lens group, and a second vent through which the groove is connected to an outer space of the lens barrel. The cover member includes a third vent connected to the second vent.

The first to third vents may be disposed at intervals in a circumferential direction around the optical axis of the lens barrel.

The first vent may face a first direction intersecting the optical axis of the lens barrel, and the second vent may face in a second direction intersecting the optical axis.

The first vent, the second vent, and the third vent may face different directions.

The first vent and the second vent may have different sizes.

The first vent, the second vent, and the third vent may have different sizes.

The first vent may be closer to the first lens group than the second vent.

The camera module may further include a moisture-absorbing member disposed in the groove.

In a direction of the optical axis, the first vent and the second vent may be closer to the first lens group than to the moisture-absorbing member.

The camera module may further include an adhesive member for fixing the cover member to the lens barrel.

Other features and aspects will be apparent from the following detailed description, the drawings, and the claims.

### BRIEF DESCRIPTION OF DRAWINGS

FIG. 1 is a configuration diagram of a camera module according to an example embodiment of the present disclosure.

FIG. 2 is a cross-sectional view of the camera module illustrated in FIG. 1.

FIGS. 3 to 5 are cross-sectional views of modified examples of the camera module illustrated in FIG. 1.

FIG. 6 is a configuration diagram of a camera module according to another example embodiment of the present disclosure.

FIG. 7 is a cross-sectional view of the camera module illustrated in FIG. 6.

FIGS. 8 to 10 are cross-sectional views of modified examples of the camera module illustrated in FIG. 6.

FIG. 11 is a configuration diagram of a camera module according to another example embodiment of the present disclosure.

FIG. 12 is a cross-sectional view of the camera module illustrated in FIG. 11.

FIGS. 13 to 15 are cross-sectional views of modified examples of the camera module illustrated in FIG. 11.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being "on," "connected to," or "coupled to" another element, it may be directly "on," "connected to," or "coupled to" the other element, or there may be one or more other elements intervening therebetween. In contrast, when an element is described as being "directly on," "directly connected to," or "directly coupled to" another element, there can be no other elements intervening therebetween.

As used herein, the term "and/or" includes any one and any combination of any two or more of the associated listed items; likewise, "at least one of" includes any one and any combination of any two or more of the associated listed items.

Although terms such as "first," "second," and "third" may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as "above," "upper," "below," "lower," and the like, may be used herein for ease of description to describe one element’s relationship to another element as shown in the figures. Such spatially relative terms are intended to encompass different orientations of the device in use or operation in addition to the orientation depicted in the figures. For example, if the device in the figures is turned over, an element described as being "above," or "upper" relative to another element would then be "below," or "lower" relative to the other element. Thus, the term "above" encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles "a," "an," and "the" are intended to include the plural forms as well, unless the context clearly indicates otherwise. The terms "comprises," "includes," and "has" specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term "may" with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

A camera module according to an aspect of the present disclosure may include a plurality of lens groups. For example, the camera module according to this aspect may include a first lens group and a second lens group sequentially disposed along an optical axis. The camera module according to this aspect may include a lens barrel. The lens barrel may be formed to accommodate the first lens group and the second lens group. The camera module according to this aspect may enable ventilation between the inner space and outer space of the camera module. For example, the lens barrel of the camera module according to this aspect may include a first vent and a second vent through which external air may flow in and internal air may be discharged. In addition, the camera module according to this aspect may include a configuration for removing moisture in air that flows in or is discharged through the first vent or the second vent. For example, a moisture-absorbing member may be disposed in a groove in the lens barrel.

A camera module according to another aspect of the present disclosure may include a plurality of lens groups. For example, the camera module according to this aspect may include a first lens group and a second lens group sequentially disposed along an optical axis. The camera module according to this aspect may include a configuration for accommodating or fixing the first lens group and the second lens group. For example, the camera module according to this aspect may include a lens barrel that accommodates the second lens group and a cover member for fixing the first lens group to the lens barrel. The camera module according to this aspect may enable ventilation between the inner space and outer space of the camera module. For example, the lens barrel and the cover member of the camera module according to this aspect may include a first vent, a second vent, and a third vent through which external air may flow in or internal air may be discharged.

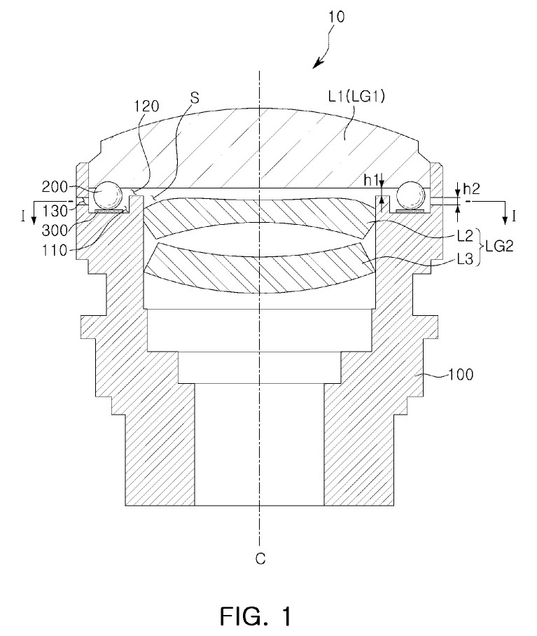

Hereinafter, an example embodiment of the present disclosure will be described in detail with reference to the accompanying exemplary drawings. First, an example embodiment of a camera module will be described with reference to FIGS. 1 to 5.

A camera module 10 according to this example embodiment may include a lens barrel 100, a first lens group LG1, and a second lens group LG2. However, the camera module 10 is not limited to the above-described members. For example, the camera module 10 may further include a buffer member 200 and a moisture-absorbing member 300.

The lens barrel 100 may be formed to accommodate a plurality of lens groups. For example, inside the lens barrel 100, the first lens group LG1 and the second lens group LG2 may be sequentially disposed along an optical axis C. For reference, although the drawings illustrate only the first lens group LG1 and the second lens group LG2 as being sequentially disposed inside the lens barrel 100, the number of lens groups disposed inside the lens barrel 100 is not limited to two. For example, a third lens group disposed on an image side of the second lens group LG2 may be further disposed inside the lens barrel 100.

The lens barrel 100 may be formed to accommodate the buffer member 200 and the moisture-absorbing member 300. For example, as illustrated in FIG. 1, a groove 110 may be formed in the vicinity of one side of the lens barrel 100. The groove 110 may extend in a circumferential direction of the lens barrel 100 and may have a predetermined depth. To provide further description, the groove 110 may be formed in a circular shape along an edge of the first lens group LG1. The groove 110 may be formed at a position substantially facing a rib of the first lens group LG1 (i.e., a portion of the first lens group LG1 other than an effective diameter thereof).

The first lens group LG1 may include at least one lens. For example, the first lens group LG1 may include a first lens L1. However, the configuration of the first lens group LG1 is not limited to the first lens L1. For example, the first lens group LG1 may include a cover glass, or include the cover glass and the first lens L1. The first lens L1 may have refractive power. For example, the first lens L1 may have positive or negative refractive power. The first lens L1 may be formed of a material resistant to external impact. For example, the first lens L1 may be formed of a glass material. However, the material of the first lens L1 is not limited to glass. The first lens L1 may be disposed to cover one side of the lens barrel 100. For example, the first lens L1 may be substantially the same size as an opening in one side of the lens barrel 100 to be firmly coupled to one end of the lens barrel 100.

The second lens group LG2 may include a plurality of lenses. For example, the second lens group LG2 may include a second lens L2 and a third lens L3. However, the configuration of the second lens group LG2 is not limited to the second lens L2 and the third lens L3. In an example, the second lens group LG2 may further include a fourth lens. In another example, the second lens group LG2 may further include fourth to seventh lenses. The second lens group LG2 may include a lens of a material different from that of the first lens L1. For example, at least one of the second lens L2 and the third lens L3 included in the second lens group LG2 may be formed of a plastic material. However, the materials of the second lens L2 and the third lens L3 are not limited to plastic. The second lens L2 and the third lens L3 may be firmly fixed inside the lens barrel 100. For example, the second lens L2 and the third lens L3 may be stably positioned inside the lens barrel 100 via a spacing-maintaining member or the like.

The buffer member 200 may be disposed in the lens barrel 100. For example, the buffer member 200 may be disposed in the groove 110 of the lens barrel 100. The buffer member 200 may be formed in a shape substantially the same as or similar to that of the groove 110. In an example, the buffer member 200 may be formed in a circular shape. In another example, the buffer member 200 may be formed in a ring shape having one end and a distal end while having a length substantially the same as or similar to that of the groove 110. The buffer member 200 may stably support the edge of the first lens group LG1 or an edge of the first lens L1. In an example, the buffer member 200 may support the first lens group LG1 or the first lens L1 at a predetermined height. In another example, the buffer member 200 may support the first lens group LG1 or the first lens L1 so that the optical axis C of the first lens group LG1 or the first lens L1 coincides with the optical axis C of the lens barrel 100. The buffer member 200 may be formed of an elastically deformable material. In an example, the buffer member 200 may be formed of a rubber material. In another example, to facilitate a change in formation of the buffer member 200, the buffer member 200 may be formed of a plastic material. In another example, to allow air to flow in and be discharged through the buffer member 200, the buffer member 200 may be formed of a perforated material.

The moisture-absorbing member 300 may be disposed in the groove 110 of the lens barrel 100. In an example, the moisture-absorbing member 300 may be disposed at a predetermined height on a bottom surface of the groove 110. In another example, the moisture-absorbing member 300 may be disposed below the buffer member 200. The moisture-absorbing member 300 may enable air to flow in and be discharged. For example, the moisture-absorbing member 300 may include a plurality of fine holes. The moisture-absorbing member 300 may capture or retain moisture in air. For example, the moisture-absorbing member 300 may include silica gel capable of adsorbing moisture in air.

In the camera module 10 according to this example embodiment, air in a first space S between the first lens group LG1 and the second lens group LG2 may be discharged outward from the lens barrel 100, or external air of the lens barrel 100 may flow into the first space S between the first lens group LG1 and the second lens group LG2. For example, the lens barrel 100 may include a first vent 120 and a second vent 130 through which air may flow in and be discharged. The first vent 120 may enable air discharge from the first space S to the groove 110 or air inflow from the groove 110 to the first space S. The second vent 130 may enable air discharge from the groove 110 to an outside of the lens barrel 100 or air inflow from the outside of the lens barrel 100 to the groove 110.

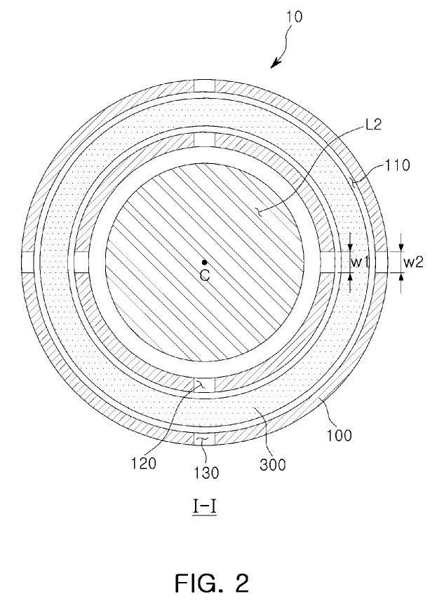

As illustrated in FIG. 2, the first vent 120 and the second vent 130 may be formed at an interval along the circumferential direction around the optical axis C of the lens barrel 100. For example, the same number of first vents 120 and second vents 130 may be formed around the optical axis C. For reference, although FIG. 2 illustrates four first vents 120 and four second vents 130, the number of each of the first vents 120 and the second vents 130 is not limited to four. For example, five or more first vents 120 and five or more second vents 130 may be formed. The first vent 120 and the second vent 130 may each have predetermined sizes. For example, the first vent 120 may have a first width w1 and a first height h1, and the second vent 130 may have a second width w2 and a second height h2. According to this aspect, the first width w1 and the second widthw2 may be substantially the same size as each other, and the first height h1 and the second height h2 may be substantially the same size as each other.

The first vent 120 and the second vent 130 may be formed at different heights. In an example, the first vent 120 and the second vent 130 may be higher than the moisture-absorbing member 300. To provide further description, the first vent 120 and the second vent 130 may be closer to the first lens group LG1 than to the moisture-absorbing member 300 in a direction of the optical axis C. In another example, the first vent 120 may be closer to the first lens group LG1 than the second vent 130. Such an arrangement of the first vent 120 and the second vent 130 may increase a length of a flow path through which air sequentially moves through the first vent 120, the moisture-absorbing member 300, and the second vent 130.

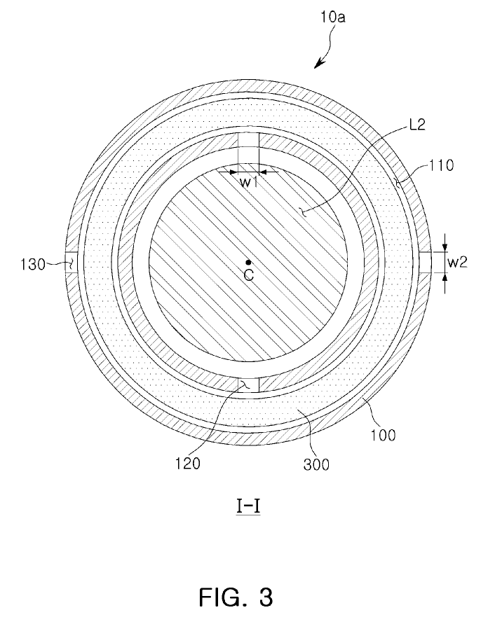

The first vent 120 and the second vent 130 may be formed in unique shapes as necessary. In an example, a camera module 10a according to a first modified example may include the first vent 120 and the second vent 130 facing different directions, as illustrated in FIG. 3. To provide further description, the first vent 120 may face a first direction intersecting the optical axis C, and the second vent 130 may face a second direction intersecting the optical axis C. Such an arrangement of the first vent 120 and the second vent 130 may increase a length of an air flow path through which the first vent 120 is connected to the second vent 130, thereby improving an effect of moisture removal by using the moisture-absorbing member 300.

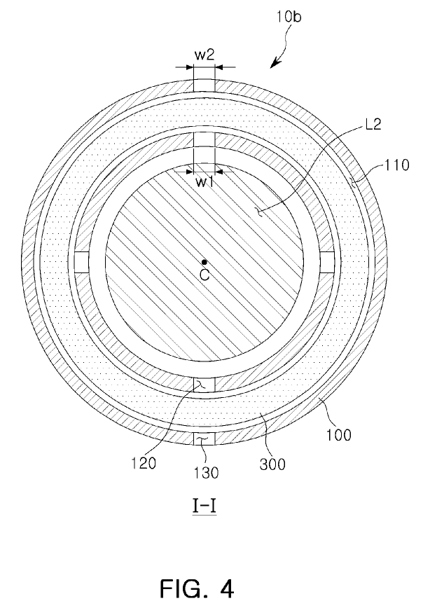

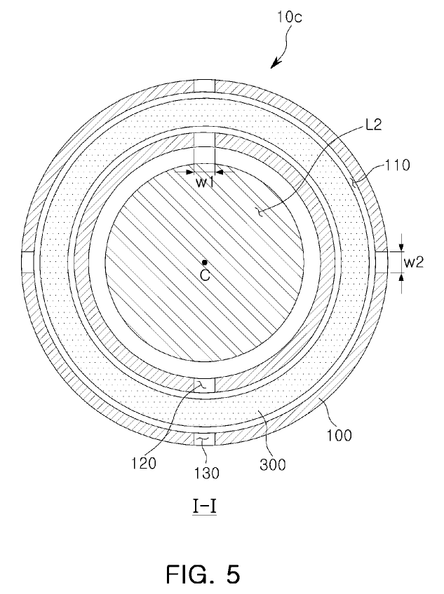

In another example, camera modules 10b and 10c according to second and third modified examples may include different numbers of first vents 120 and second vents 130, as illustrated in FIGS. 4 and 5. To provide further description, in the camera module 10b according to the second modified example, the number of first vents 120 may be greater than the number of second vents 130 (see FIG. 4), and in the camera module 10c according to the third modified example, the number of second vents 130 may be greater than the number of first vents 120 (see FIG. 5). Such an arrangement of the first vent 120 and the second vent 130 may improve an effect of air inflow or discharge through the first vent 120 or the second vent 130, while obtaining an effect of partially extending the air flow path through which the first vent 120 is connected to the second vent 130.

In another example, the first vent 120 and the second vent 130 may have different sizes. To provide further description, the first width w1 of the first vent 120 and the second width w2 of the second vent 130 may have different sizes. Alternatively, the first height h1 of the first vent 120 and the second height h2 of the second vent 130 may have different sizes.

The camera module 10 as configured above may enable air circulation between the inner space and outer space of the lens barrel 100 through the plurality of first vents 120 and second vents 130, thereby suppressing occurrence of a condensation phenomenon that may occur in the first space S between the first lens group LG1 and the second lens group LG2. In addition, the camera module 10 according to this example embodiment may include the moisture-absorbing member 300 disposed between the first space S and the outer space of the lens barrel 100 (or the groove 110), thereby effectively removing moisture in circulating air.

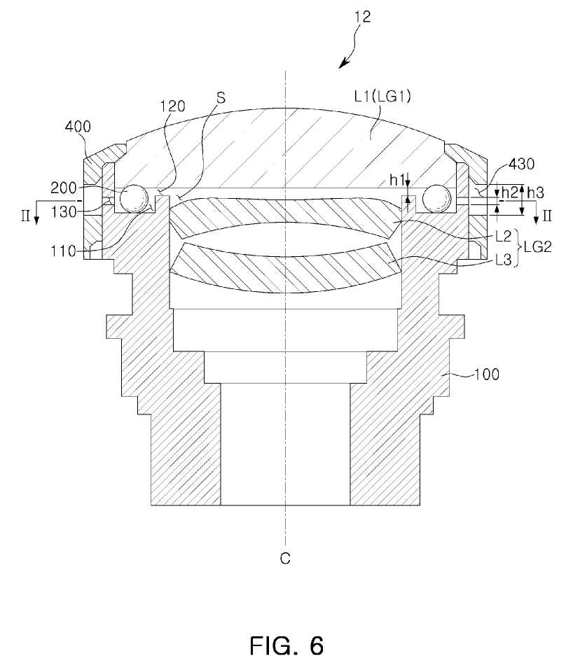

Next, a camera module according to another example embodiment will be described with reference to FIGS. 6 to 10.

A camera module 12 according to this example embodiment may include a lens barrel 100, a first lens group LG1, and a second lens group LG2. However, the camera module 12 is not limited to the above-described members. For example, the camera module 12 may further include a buffer member 200 and a cover member 400.

The lens barrel 100 may accommodate a plurality of lens groups. For example, inside the lens barrel 100, the first lens group LG1 and the second lens group LG2 may be sequentially disposed along an optical axis C. For reference, although the drawings illustrate only the first lens group LG1 and the second lens group LG2 as being sequentially disposed inside the lens barrel 100, the number of lens groups disposed inside the lens barrel 100 is not limited to two. For example, a third lens group disposed on an image side of the second lens group LG2 may be further disposed inside the lens barrel 100.

The lens barrel 100 may accommodate the buffer member 200. For example, as illustrated in FIG. 6, a groove 110 may be formed in the vicinity of one side of the lens barrel 100. The groove 110 may extend in a circumferential direction of the lens barrel 100 and may have a predetermined depth. To provide further description, the groove 110 may be formed in a circular shape along an edge of the first lens group LG1. The groove 110 may be formed at a position substantially facing a rib of the first lens group LG1 (i.e., a portion of the first lens group LG1 other than an effective diameter thereof). The lens barrel 100 may include a configuration that enables inflow of external air to discharge of internal air. To provide further description, at least one first vent 120 and at least one second vent 130 may be formed on a side surface of the lens barrel 100.

The cover member 400 may be coupled to the lens barrel 100. In an example, the cover member 400 may be firmly coupled to one end of the lens barrel 100 by press-fitting or screw-fastening. In another example, the cover member 400 may be firmly coupled to the lens barrel 100 by using an adhesive member.

The cover member 400 may prevent the first lens group LG1 from being separated from the lens barrel 100. For example, the cover member 400 may be coupled to the lens barrel 100 while pressing an edge of the first lens group LG1, thereby firmly fixing the first lens group LG1 to one end of the lens barrel 100. The cover member 400 may include a configuration that enables inflow of external air or discharge of internal air. To provide further description, at least one third vent 430 may be formed on a side surface of the cover member 400.

The first lens group LG1 may include at least one lens. For example, the first lens group LG1 may include a first lens L1. However, the configuration of the first lens group LG1 is not limited to the first lens L1. For example, the first lens group LG1 may include a cover glass, or include the cover glass and the first lens L1. The first lens L1 may have refractive power. For example, the first lens L1 may have positive or negative refractive power. The first lens L1 may be formed of a material resistant to external impact. For example, the first lens L1 may be formed of a glass material. However, the material of the first lens L1 is not limited to glass. The first lens L1 may be disposed to cover one side of the lens barrel 100.

The second lens group LG2 may include a plurality of lenses. For example, the second lens group LG2 may include a second lens L2 and a third lens L3. However, the configuration of the second lens group LG2 is not limited to the second lens L2 and the third lens L3. In an example, the second lens group LG2 may further include a fourth lens. In another example, the second lens group LG2 may further include fourth to seventh lenses. The second lens group LG2 may include a lens of a material different from that of the first lens L1. For example, at least one of the second lens L2 and the third lens L3 included in the second lens group LG2 may be formed of a plastic material. However, the materials of the second lens L2 and the third lens L3 are not limited to plastic. The second lens L2 and the third lens L3 may be firmly fixed inside the lens barrel 100. For example, the second lens L2 and the third lens L3 may be stably positioned inside the lens barrel 100 via a spacing-maintaining member or the like.

The buffer member 200 may be disposed in the lens barrel 100. For example, the buffer member 200 may be disposed in the groove 110 of the lens barrel 100. The buffer member 200 may be formed in a shape substantially the same as or similar to that of the groove 110. In an example, the buffer member 200 may be formed in a circular shape. In another example, the buffer member 200 may be formed in a ring shape having one end and a distal end while having a length substantially the same as or similar to that of the groove 110. The buffer member 200 may stably support the edge of the first lens group LG1 or an edge of the first lens L1. In an example, the buffer member 200 may support the first lens group LG1 or the first lens L1 at a predetermined height. In another example, the buffer member 200 may support the first lens group LG1 or the first lens L1 so that the optical axis C of the first lens group LG1 or the first lens L1 coincides with the optical axis C of the lens barrel 100. The buffer member 200 may be formed of an elastically deformable material. In an example, the buffer member 200 may be formed of a rubber material. In another example, to facilitate a change in formation of the buffer member 200, the buffer member 200 may be formed of a plastic material. In another example, to allow air to flow in and be discharged through the buffer member 200, the buffer member 200 may be formed of a perforated material.

In the camera module 12 according to this example embodiment, air in a first space S between the first lens group LG1 and the second lens group LG2 may be discharged outward from the lens barrel 100, or external air of the lens barrel 100 may flow into the first space S between the first lens group LG1 and the second lens group LG2. For example, the lens barrel 100 and the cover member 400 may include first, second, and third vents 120, 130, and 430 through which air may flow in and be discharged. The first vent 120 may enable air discharge from the first space S to the groove 110 or air inflow from the groove 110 to the first space S. The second vent 130 and the third vent 430 may enable air discharge from the groove 110 to an outside of the lens barrel 100 or air inflow from the outside of the lens barrel 100 to the groove 110.

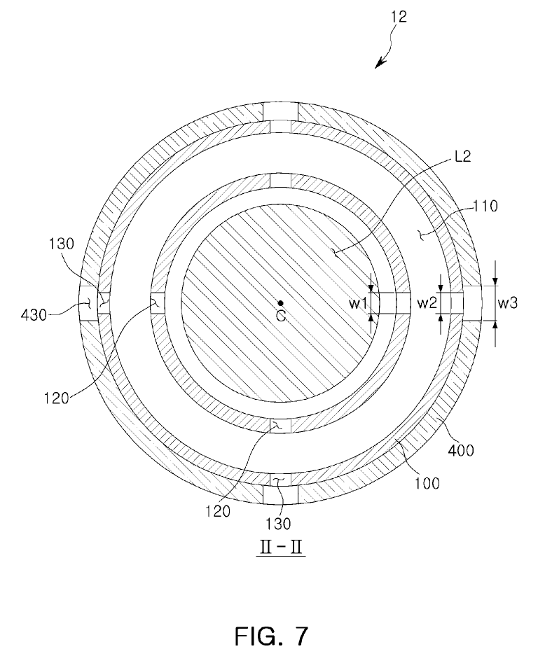

As illustrated in FIG. 7, the first vent 120, the second vent 130, and the third vent 430 may be formed at intervals in a circumferential direction around the optical axis C of the lens barrel 100. For example, the same number of first vents 120, second vents 130, and third vents 430 may be formed around the optical axis C. For reference, although FIG. 7 illustrates four first vents 120, four second vents 130, and four third vents 430, the number of respective vents is not limited to four. For example, five or more first vents 120, five or more second vents 130, and five or more third vents 430 may be formed. The first vent 120, the second vent 130, and the third vent 430 may each have predetermined sizes. For example, the first vent 120 may have a first width w1 and a first height h1, the second vent 130 may have a second width w2 and a second height h2, and the third vent 430 may have a third width w3 and a third height h3. According to this aspect, the first width w1, the second width w2, and the third width w3 may be substantially the same size as one another, and the first height h1, the second height h2, and the third height h3 may be substantially the same size as one another.

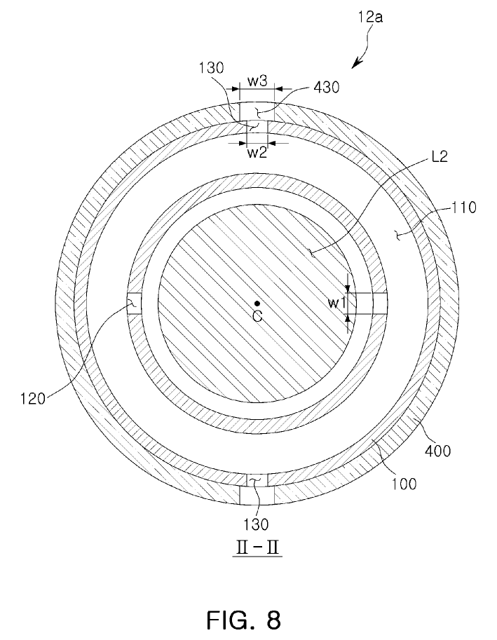

The first vent 120, the second vent 130, and the third vent 430 may be formed in unique shapes as necessary. In an example, a camera module 12a according to a first modified example may include the first vent 120, the second vent 130, and the third vent 430 facing different directions, as illustrated in FIG. 8. To provide further description, the first vent 120 may face a first direction intersecting the optical axis C, and the second vent 130 and the third vent 430 may face a second direction intersecting the optical axis C. Such an arrangement of the first vent 120, the second vent 130, and the third vent 430 may increase a length of an air flow path through which the first vent 120 is connected to the second vent 130.

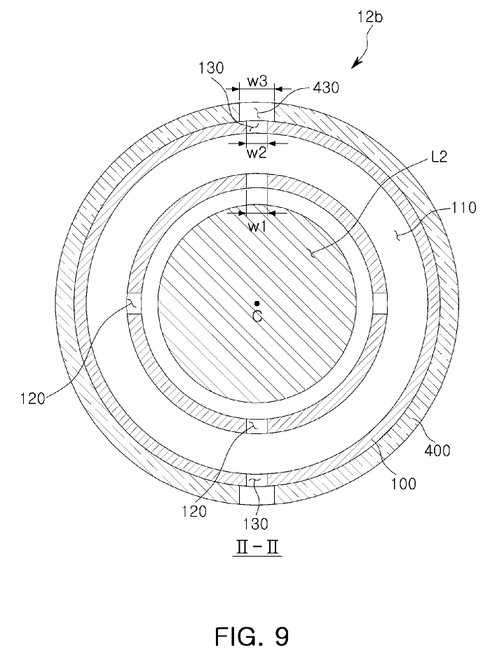

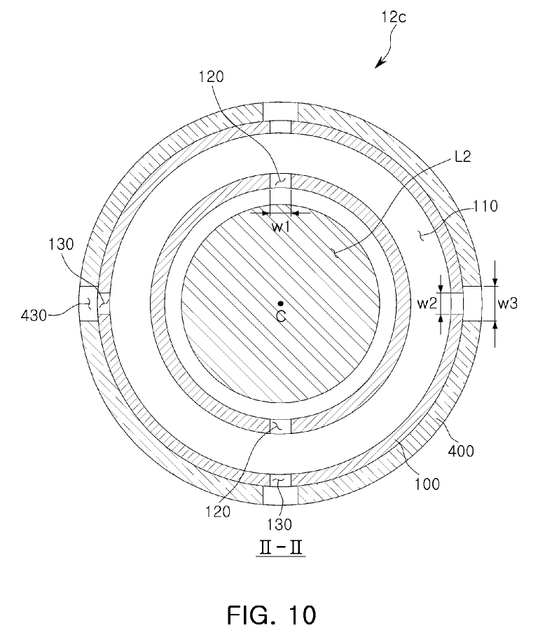

In another example, camera modules 12b and 12c according to second and third modified examples may include different numbers of first vents 120, second vents 130, and third vents 430, as illustrated in FIGS. 9 and 10. To provide further description, in the camera module 12b according to the second modified example, the number of first vents 120 may be greater than the number of second vents 130 and third vents 430 (see FIG. 9), and in the camera module 12c according to the third modified example, the number of second vents 130 and third vents 430 may be greater than the number of first vents 120 (see FIG. 10). Such an arrangement of the first vent 120 and the second vent 130 may improve an effect of air inflow or discharge through the first vent 120, the second vent 130, or the third vent 430, while obtaining an effect of partially extending the air flow path through which the first vent 120 is connected to the second vent 130 or the third vent 430.

In another example, the first vent 120, the second vent 130, and the third vent 430 may have different sizes. To provide further description, at least one pair among the first width w1 of the first vent 120, the second width w2 of the second vent 130, and the third width w3 of the third vent 430 may have different sizes. Alternatively, at least one pair among the first height h1 of the first vent 120, the second height h2 of the second vent 130, and the third height h3 of the third vent 430 may have different sizes.

The camera module 12 as configured above may enable air circulation between the inner space and outer space of the lens barrel 100 through the plurality of first vents 120 and second vents 130, thereby suppressing occurrence of a condensation phenomenon that may occur in the first space S between the first lens group LG1 and the second lens group LG2.

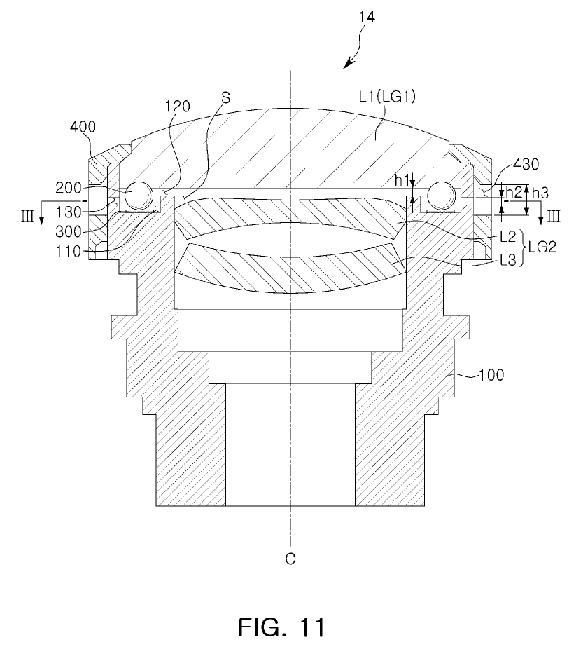

Next, another example embodiment of a camera module will be described with reference to FIGS. 11 to 15.

A camera module 14 according to this example embodiment may include a lens barrel 100, a first lens group LG1, and a second lens group LG2. However, the camera module 14 is not limited to the above-described members. For example, the camera module 14 may further include a buffer member 200, a moisture-absorbing member 300, and a cover member 400.

The lens barrel 100 may accommodate a plurality of lens groups. For example, inside the lens barrel 100, the first lens group LG1 and the second lens group LG2 may be sequentially disposed along an optical axis C. For reference, although the drawings illustrate only the first lens group LG1 and the second lens group LG2 as being sequentially disposed inside the lens barrel 100, the number of lens groups disposed inside the lens barrel 100 is not limited to two. For example, a third lens group disposed on an image side of the second lens group LG2 may be further disposed inside the lens barrel 100.

The lens barrel 100 may accommodate the buffer member 200. For example, as illustrated in FIG. 11, a groove 110 may be formed in the vicinity of one side of the lens barrel 100. The groove 110 may extend in a circumferential direction of the lens barrel 100 and may have a predetermined depth. To provide further description, the groove 110 may be formed in a circular shape along an edge of the first lens group LG1. The groove 110 may be formed at a position substantially facing a rib of the first lens group LG1 (i.e., a portion of the first lens group LG1 other than an effective diameter thereof). The lens barrel 100 may include a configuration that enables inflow of external air or discharge of internal air. To provide further description, at least one first vent 120 and at least one second vent 130 may be formed on a side surface of the lens barrel 100.

The moisture-absorbing member 300 may be disposed in the groove 110 of the lens barrel 100. In an example, the moisture-absorbing member 300 may be disposed at a predetermined height on a bottom surface of the groove 110. In another example, the moisture-absorbing member 300 may be disposed below the buffer member 200. The moisture-absorbing member 300 may enable air to flow in and be discharged. For example, the moisture-absorbing member 300 may include a plurality of fine holes. The moisture-absorbing member 300 may capture or retain moisture in air. For example, the moisture-absorbing member 300 may include silica gel capable of adsorbing moisture in air.

The cover member 400 may be coupled to the lens barrel 100. In an example, the cover member 400 may be firmly coupled to one end of the lens barrel 100 by press-fitting or screw-fastening. In another example, the cover member 400 may be firmly coupled to the lens barrel 100 by using an adhesive member.

The cover member 400 may prevent the first lens group LG1 from being separated from the lens barrel 100. For example, the cover member 400 may be coupled to the lens barrel 100 while pressing an edge of the first lens group LG1, thereby firmly fixing the first lens group LG1 to one end of the lens barrel 100. The cover member 400 may include a configuration that enables inflow of external air or discharge of internal air. To provide further description, at least one third vent 430 may be formed on a side surface of the cover member 400.

The first lens group LG1 may include at least one lens. For example, the first lens group LG1 may include a first lens L1. However, the configuration of the first lens group LG1 is not limited to the first lens L1. For example, the first lens group LG1 may include a cover glass, or include the cover glass and the first lens L1. The first lens L1 may have refractive power. For example, the first lens L1 may have positive or negative refractive power. The first lens L1 may be formed of a material resistant to external impact. For example, the first lens L1 may be formed of a glass material. However, the material of the first lens L1 is not limited to glass. The first lens L1 may be disposed to cover one side of the lens barrel 100.

The second lens group LG2 may include a plurality of lenses. For example, the second lens group LG2 may include a second lens L2 and a third lens L3. However, the configuration of the second lens group LG2 is not limited to the second lens L2 and the third lens L3. In an example, the second lens group LG2 may further include a fourth lens. In another example, the second lens group LG2 may further include fourth to seventh lenses. The second lens group LG2 may include a lens of a material different from that of the first lens L1. For example, at least one of the second lens L2 and the third lens L3 included in the second lens group LG2 may be formed of a plastic material. However, the materials of the second lens L2 and the third lens L3 are not limited to plastic. The second lens L2 and the third lens L3 may be firmly fixed inside the lens barrel 100. For example, the second lens L2 and the third lens L3 may be stably positioned inside the lens barrel 100 via a spacing-maintaining member or the like.

The buffer member 200 may be disposed in the lens barrel 100. For example, the buffer member 200 may be disposed in the groove 110 of the lens barrel 100. The buffer member 200 may be formed in a shape substantially the same as or similar to that of the groove 110. In an example, the buffer member 200 may be formed in a circular shape. In another example, the buffer member 200 may be formed in a ring shape having one end and a distal end while having a length substantially the same as or similar to that of the groove 110. The buffer member 200 may stably support the edge of the first lens group LG1 or an edge of the first lens L1. In an example, the buffer member 200 may support the first lens group LG1 or the first lens L1 at a predetermined height. In another example, the buffer member 200 may support the first lens group LG1 or the first lens L1 so that the optical axis C of the first lens group LG1 or the first lens L1 coincides with the optical axis C of the lens barrel 100. The buffer member 200 may be formed of an elastically deformable material. In an example, the buffer member 200 may be formed of a rubber material. In another example, to facilitate a change in formation of the buffer member 200, the buffer member 200 may be formed of a plastic material. In another example, to allow air to flow in and be discharged through the buffer member 200, the buffer member 200 may be formed of a perforated material.

In the camera module 14 according to this example embodiment, air in a first space S between the first lens group LG1 and the second lens group LG2 may be discharged outward from the lens barrel 100, or external air of the lens barrel 100 may flow into the first space S between the first lens group LG1 and the second lens group LG2. For example, the lens barrel 100 and the cover member 400 may include first, second, and third vents 120, 130, and 430 through which air may flow in and be discharged. The first vent 120 may enable air discharge from the first space S to the groove 110 or air inflow from the groove 110 to the first space S. The second vent 130 and the third vent 430 may enable air discharge from the groove 110 to an outside of the lens barrel 100 or air inflow from the outside of the lens barrel 100 to the groove 110.

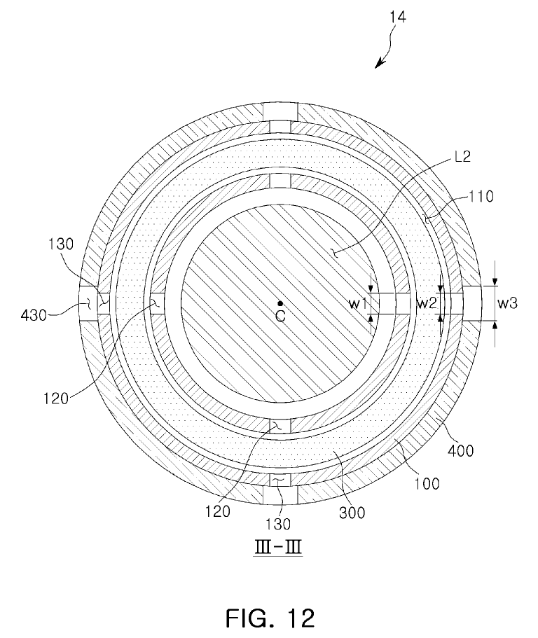

As illustrated in FIG. 12, the first vent 120, the second vent 130, and the third vent 430 may be formed at intervals in a circumferential direction around the optical axis C of the lens barrel 100. For example, the same number of first vents 120, second vents 130, and third vents 430 may be formed around the optical axis C. For reference, although FIG. 12 illustrates four first vents 120, four second vents 130, and four third vents 430, the number of respective vents is not limited to four. For example, five or more first vents 120, five or more second vents 130, and five or more third vents 430 may be formed. The first vent 120, the second vent 130, and the third vent 430 may each have predetermined sizes. For example, the first vent 120 may have a first width w1 and a first height h1, the second vent 130 may have a second width w2 and a second height h2, and the third vent 430 may have a third width w3 and a third height h3. According to this aspect, the first width w1, the second width w2, and the third width w3 may be substantially the same size as one another, and the first height h1, the second height h2, and the third height h3 may be substantially the same size as one another.

The first vent 120, the second vent 130, and the third vent 430 may be formed at different heights. In an example, the first vent 120, the second vent 130, and the third vent 430 may be higher than the moisture-absorbing member 300. To provide further description, the first vent 120, the second vent 130, and the third vent 430 may be closer to the first lens group LG1 than to the moisture-absorbing member 300 in a direction of the optical axis C. In another example, the first vent 120 may be closer to the first lens group LG1 than the second vent 130 or the third vent 430. Such an arrangement of the first vent 120, the second vent 130, and the third vent 430 may increase a length of an air flow path compared to a case where the first vent 120, the moisture-absorbing member 300, the second vent 130, and the third vent 430 are formed at the same height.

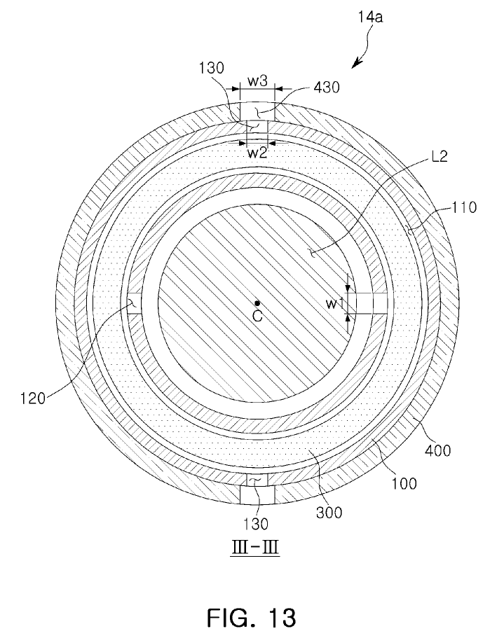

The first vent 120, the second vent 130, and the third vent 430 may be formed in unique shapes as necessary. In an example, a camera module 14a according to a first modified example may include the first vent 120, the second vent 130, and the third vent 430 facing different directions, as illustrated in FIG. 13. To provide further description, the first vent 120 may face a first direction intersecting the optical axis C, and the second vent 130 and the third vent 430 may face a second direction intersecting the optical axis C. Such an arrangement of the first vent 120, the second vent 130, and the third vent 430 may increase a length of an air flow path through which the first vent 120 is connected to the second vent 130, thereby improving a dehumidification effect by using the moisture-absorbing member.

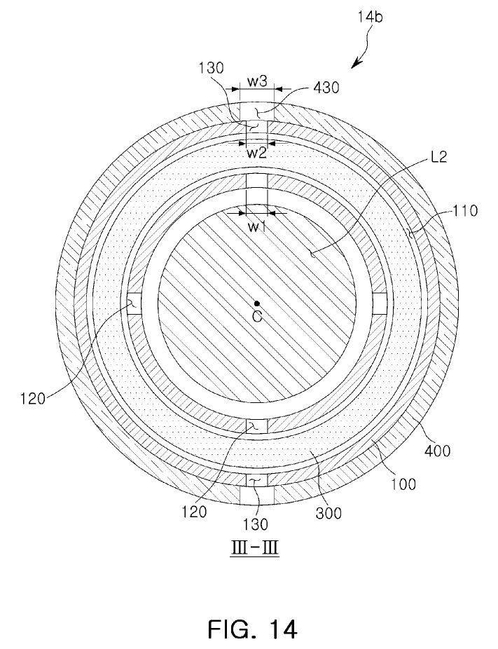

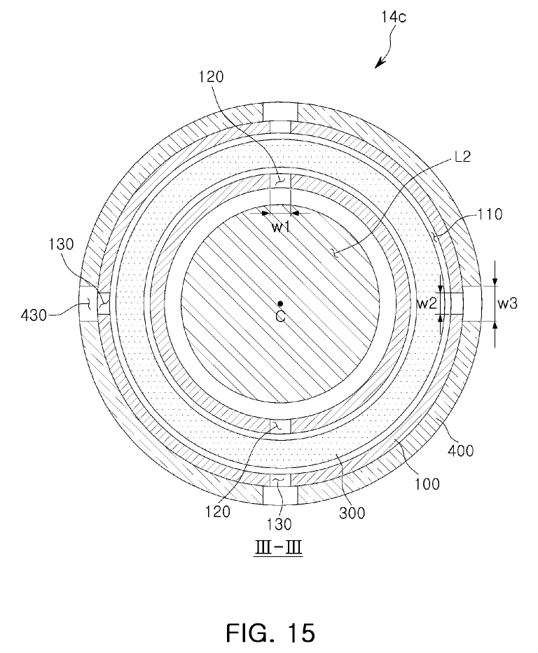

In another example, camera modules 14b and 14c according to second and third modified examples may include different numbers of first vents 120, second vents 130, and third vents 430, as illustrated in FIGS. 14 and 15. To provide further description, in the camera module 14b according to the second modified example, the number of first vents 120 may be greater than the number of second vents 130 and third vents 430 (see FIG. 14), and in the camera module 14c according to the third modified example, the number of second vents 130 and third vents 430 may be greater than the number of first vent 120 (see FIG. 15). Such an arrangement of the first vent 120 and the second vent 130 may improve an effect of air inflow or discharge through the first vent 120, the second vent 130, and the third vent 430, while obtaining an effect of partially extending the air flow path through which the first vent 120 is connected to the second vent 130 or the third vent 430.

In another example, the first vent 120, the second vent 130, and the third vent 430 may have different sizes. To provide further description, at least one pair among the first width w1 of the first vent 120, the second width w2 of the second vent 130, and the third width w3 of the third vent 430 may have different sizes. Alternatively, at least one pair among the first height h1 of the first vent 120, the second height h2 of the second vent 130, and the third height h3 of the third vent 430 may have different sizes.

The camera module 14 as configured above may enable air circulation between the inner space and outer space of the lens barrel 100 through the plurality of first vents 120 and second vents 130, thereby suppressing occurrence of a condensation phenomenon that may occur in the first space S between the first lens group LG1 and the second lens group LG2. In addition, the camera module 14 according to this example embodiment may include the moisture-absorbing member 300 disposed between the first space S and the outer space of the lens barrel 100 (or the groove 110), thereby effectively removing moisture in circulating air.

An aspect of the present disclosure is to provide a camera module capable of reducing a dew condensation phenomenon that may occur between the first and second lens groups of the camera module.

As set forth above, the present disclosure may effectively suppress or reduce the dew condensation phenomenon that may occur between the first lens group and the second lens group of the camera module.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A camera module comprising:
a first lens group and a second lens group sequentially disposed along an optical axis;
a lens barrel configured to accommodate the first lens group and the second lens group; and
a moisture-absorbing member disposed in a groove in the lens barrel,
wherein the lens barrel comprises a first vent through which the groove is connected to a space between the first lens group and the second lens group, and a second vent through which the groove is connected to an outer space of the lens barrel.

2. The camera module of claim 1, wherein the first vent and the second vent are disposed at intervals in a circumferential direction around the optical axis of the lens barrel.

3. The camera module of claim 1, wherein the first vent faces a first direction intersecting the optical axis of the lens barrel, and the second vent faces in a second direction intersecting the optical axis.

4. The camera module of claim 1, wherein a number of first vents and a number of second vents are different.

5. The camera module of claim 1, wherein the first vent and the second vent have different sizes.

6. The camera module of claim 1, further comprising a buffer member disposed in the groove.

7. A camera module comprising:
a first lens group and a second lens group sequentially disposed along an optical axis;
a lens barrel configured to accommodate the second lens group; and
a cover member configured to fix the first lens group to the lens barrel,
wherein the lens barrel comprises a groove, a first vent through which the groove is connected to a space between the first lens group and the second lens group, and a second vent through which the groove is connected to an outer space of the lens barrel, and
wherein the cover member comprises a third vent connected to the second vent.

8. The camera module of claim 7, wherein the first to third vents are disposed at intervals in a circumferential direction around the optical axis of the lens barrel.

9. The camera module of claim 7, wherein the first vent faces a first direction intersecting the optical axis of the lens barrel, and the second vent faces in a second direction intersecting the optical axis.

10. The camera module of claim 7, wherein the first vent, the second vent, and the third vent face different directions.

11. The camera module of claim 7, wherein the first vent and the second vent have different sizes.

12. The camera module of claim 7, wherein the first vent, the second vent, and the third vent have different sizes.

13. The camera module of claim 7, wherein the first vent is closer to the first lens group than the second vent.

14. The camera module of claim 7, further comprising a moisture-absorbing member disposed in the groove.

15. The camera module of claim 14, wherein, in a direction of the optical axis, the first vent and the second vent are closer to the first lens group than to the moisture-absorbing member.

16. The camera module of claim 7, further comprising an adhesive member for fixing the cover member to the lens barrel.
